(19) United States
(12) Patent Application Publication
(10) Pub. No.: US 2009/0283824 A1
(43) Pub. Date: Nov. 19, 2009

(54) COOL IMPACT-IONIZATION TRANSISTOR AND METHOD FOR MAKING SAME

(75) Inventors: Thomas J. Knight, Silver Spring, MD (US); Eric J. Stewart, Silver Spring, MD (US); Joseph T. Smith, Columbia, MD (US); Sean McLaughlin, Severn, MD (US); Narsingh B. Singh, Ellicott City, MD (US)

Correspondence Address: SNELL & WILMER L.L.P. (Grumman), 600 ANTON BOULEVARD, SUITE 1400, COSTA MESA, CA, 92626, US

(73) Assignee: NORTHROP GRUMMAN SYSTEMS CORPORATION, Los Angeles, CA (US)

(21) Appl. No.: 12/258,236

(22) Filed: Oct. 24, 2008

Related U.S. Application Data
(60) Provisional application No. 60/983,663, filed on Oct. 30, 2007.

(51) Int. Cl. H01L 29/78; H01L 21/336

(52) U.S. Cl. 257/335; 438/286; 257/E29.256; 257/E21.417

(57) ABSTRACT

In one embodiment, the disclosure relates to a low-power semiconductor switching device, having a substrate supporting thereon a semiconductor body; a source electrode coupled to the semiconductor body at a source interface region; a drain electrode coupled to the semiconductor body at a drain interface region; a gate oxide film formed over a region of the semiconductor body, the gate oxide film interfacing between a gate electrode and the semiconductor body; wherein at least one of the source interface region or the drain interface region defines a sharp junction into the semiconductor body.

The application claims the filing-date benefit of Provisional Application No. 60/983,663 filed Oct. 30, 2007, the entirety of which is incorporated herein.

### BACKGROUND

1. Field of the Disclosure

The disclosure generally relates to low power transistors and more specifically to transistors having doped region geometry and material characteristics for providing extremely low sub-threshold slope.

2. Description of the Related Art

Achieving switching at very small voltages is one of the foremost obstacles to the semiconductor industry. Only a few transistor technologies have demonstrated sub-threshold voltage slopes beyond the physical thermoionic emission limit of 60 mV/decade at room temperature. Such transistors include carbon nono-tubes (CNT), quantum tunneling devices such as vertical tunnel field effect transistor (FET), and impact ionization MOSFETs (I-MOS). Of these, I-MOS may be the most attainable with potential for large scale integration and recently demonstrated sub-threshold slopes as abrupt as 10 mV/decade.

Off-state leakage tends to increase in advanced CMOS technology nodes. Scaling of transistor gate lengths by about 7% every three years lowers the power consumption by reducing drive voltage as well as capacitance. However, transistors exhibit a finite sub-threshold slope due to the statistical energy distribution of carriers. This slope defines the minimum range of voltage necessary to swing a transistor from an on state to an off state. Hence, alternative devices, such as I-MOS have been developed.

Unlike thermionically-limited devices, I-MOS depends on avalanche multiplication of carriers to switch between off-state and on-state with demonstrated sub threshold slopes of 5 mV/decade. The I-MOS devices have not developed into a useful commercial product due to two major liabilities: (1) Hot carrier injection of carriers into the gate oxide which shift the threshold voltage substantially and uncontrollably; and (2) Large drain-source voltage is necessary to generate the high electric fields necessary for minimum-size devices to avalanche. Silicon I-MOS operation has recently been reported at Vds of 8-15V. These fundamental deficiencies are insurmountable for the I-MOS devices.

FIG. 1 shows a cross section of the I-MOS transistor with avalanche breakdown occurring somewhere in the ungated I-region. Specifically, the transistor of FIG. 1 shows buried oxide layer 100, supporting gate electrode 110, source electrode 130 and semiconductor body 150. Gate electrode 130 is formed over semiconductor body 150 defines two regions L₁ and L_{Gate}. L₁ is the area in semiconductor body 150 which is not covered by gate 130, and L Gate is the area in semiconductor body 130 which is covered by gate 130. Major limitations have precluded the commercial adoption of the I-MOS transistor of FIG. 1. Such limitations include: (1) reliance on avalanche injection in close proximity to the gate lends itself to hot carrier-induced threshold instabilities, and (2) no path to scaling voltages below the International Technology Roadmap for Semiconductors (ITRS) roadmap for semiconductors of 1V has been shown.

The extremely small geometries used to achieve low voltages in I-MOS are also problematic. In fact, conventional simulations have focused on Ge instead of Si due to the lower critical E-field of Ge. Even then, geometries beyond current state of the art (25 nm and below) are necessary.

Accordingly, there is a need for low voltage transistors with low sub-threshold slope.

### SUMMARY

In one embodiment, the disclosure relates to a MOSFET comprising a substrate having a source region, a drain region and a gate region, wherein the source region includes at least one nano-dots having one or more abrupt junctions. In an embodiment of the disclosure, the abrupt junction a defines a device geometry configured for optimal impact ionization.

In another embodiment, the disclosure relates to a low-power semiconductor switching device, comprising: a substrate supporting thereon a semiconductor body; a source electrode coupled to the semiconductor body at a source interface region; a drain electrode coupled to the semiconductor body at a drain interface region; a gate oxide film formed over a region of the semiconductor body, the gate oxide film interfacing between a gate electrode and the semiconductor body; wherein at least one of the source interface region or the drain interface region defines a sharp junction into the semiconductor body.

In another embodiment, the disclosure relates to a method for providing a low-switching power transistor, the method comprising: providing a substrate having thereon a semiconductor body; forming a source electrode on the substrate, the source electrode having a source interface with the semiconductor body; forming a drain electrode on the substrate, the drain electrode having a drain interface with the semiconductor body; forming a gate electrode over a portion of the semiconductor body; defining at least one of the source interface or the drain interface to provide a sharp junction with the semiconductor body.

In still another embodiment, the disclosure relates to a rapid-switching low-voltage transistor, comprising: a source electrode; a drain electrode; a gate electrode; a semiconductor body region in electronic communication with each of the source electrode, the drain electrode and the gate electrode, the semiconductor body region having a plurality of mid-gap defect centers; the mid-gap defect centers formed as micro-plasma within a region of the semiconductor body to control a location of electronic avalanche breakdown in a region distal from the gate electrode.

In still another embodiment, the disclosure relates to a method for providing rapid-switching in a MOSFET, the method comprising: providing a semiconductor body; forming a source electrode in electronic communication with the semiconductor body, the source electrode having a source interface with the semiconductor body; forming a drain electrode in electronic communication with the semiconductor body, the drain electrode having a drain interface with the semiconductor body; forming a gate electrode over a portion of the semiconductor body; forming a plurality of mid-gap defect centers in the semiconductor body; wherein the mid-gap defect centers are formed as micro-plasma within a region of the semiconductor body for controlling a location of electronic avalanche breakdown.

In yet another embodiment, the disclosure relates to a rapid-switching low-voltage transistor device, comprising: a substrate supporting a semiconductor body; a source electrode coupled to the semiconductor body at a source interface region; a drain electrode coupled to the semiconductor body at a drain interface region; a gate oxide film formed over a region of the semiconductor body, the gate oxide film interfacing between a gate electrode and the semiconductor body; wherein at least one of the source electrode or the drain electrode includes a first nano-dot, and wherein the first nano-dot is formed from a first material having a band-gap energy lower than a band-gap energy of the semiconductor body.

In another embodiment, the disclosure relates to a method for providing rapid switching in a field-effect transistor (“FET”), comprising: providing a substrate having a semiconductor body thereon; forming a source electrode on the substrate, the source electrode having a source interface with the semiconductor body; forming a drain electrode on the substrate, the drain electrode having a drain interface with the semiconductor body; forming a gate electrode over a portion of the semiconductor body; and forming a first nano-dot within at least one of the source electrode or the drain electrode; wherein the first nano-dot is formed from a first material having a lower band-gap energy than the band-gap energy of the semiconductor body.

### BRIEF DESCRIPTION OF THE DRAWINGS

FIG. 1 is a cross-section of a prior art I-MOS device;

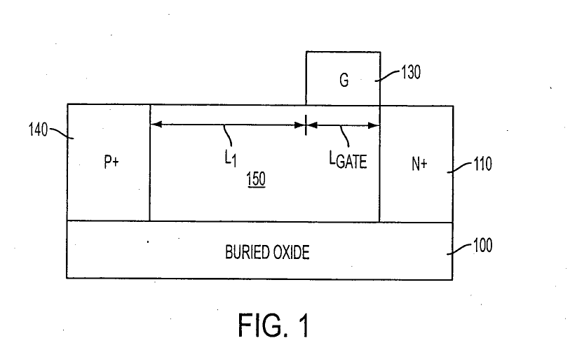

FIG. 2 is a schematic representation of a semiconductor device having one or more sharp junctions according to one embodiment of the disclosure;

FIG. 3 a schematic representation of a semiconductor device having a plurality of mid-gap defects according to another embodiment of the disclosure;

FIG. 4 is a schematic representation of a semiconductor device having a plurality of Nano-dots according to another embodiment of the disclosure; and

FIG. 5 is a graph showing simulated breakdown degradation factors as a function of junction sharpness.

### DETAILED DESCRIPTION

The embodiments disclosed herein exploit the non-thermoionic behavior of avalanche breakdown. The disclosed devices circumvent the significant problems plaguing conventional I-MOS by incorporating novel and inventive advances in epitaxy to create, among others, nanometer-scale germanium dots. The disclosed embodiments avoid the hot carrier gate oxide injection and substantially reduce the minimum operational voltage to less than Vds=1V.

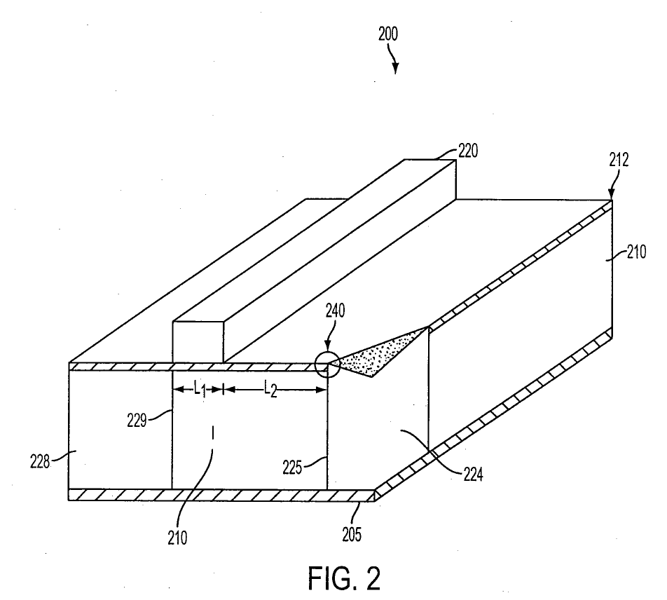

FIG. 2 shows a cool I-MOS device according to one embodiment of the disclosure. Referring to FIG. 2, device 200 comprises semiconductor body 210, gate electrode 220, source electrode 224 and drain electrode 228. Gate oxide layer 212 is interposed between gate electrode 220 and semiconductor body 210. Device 200 is typically formed over substrate 205. As shown, semiconductor body 210 supports gate electrode 220 at a top region. The area covered by gate electrode 220 in semiconductor body 210 is marked as L₁ in the I-region of semiconductor body 210. The area not covered by gate 220 in semiconductor body 210 is identified as L₂.

In the embodiment of FIG. 2, drain electrode 228 extend through the entire length of semiconductor body 210 as is conventional in the art. Consequently, interface 229 between drain electrode 228 and semiconductor body 210 is a planar junction.

In contrast, source electrode 224 is formed to have abrupt junctions 240 and 242 with semiconductor body 210. Source electrode 224 does not extend the entire length of semiconductor body 210. Depending on the application, gate oxide layer 212 may extend over the top surface of source electrode 224 or it may not (as shown). It is noted that while FIG. 2 shows source electrode 224 as having sharp junctions, drain electrode 228 may also have one or more sharp junctions. Each or both electrodes can be configured to have one or more sharp junctions. The sharp junctions can protrude or extend into the semiconductor body 210 such that the interface between each electrode and the semiconductor body 210 is not a planar, flat interface. Sharp junctions 225, focuses the electrical field at a particular point in the semiconductor body as opposed to spreading it across a flat interface.

Introducing sharp junction 225, at the interface between the semiconductor body and one or more of the electrodes addresses the prior art deficiencies. The junction between the electrode (e.g., P+ region) and the I-region of the semiconductor body in the conventional I-MOS transistor is essentially a planar junction. As such, the electric field at breakdown is distributed throughout the interface surface. Sharp and abrupt junction 225, (as shown in the exemplary embodiment of FIG. 2), however, can reach avalanche breakdown at 5 or even 10 times lower potential. By creating a non-planar junction, the peak electric field is substantially increased which translates into a relaxation of the necessary geometry and a decrease in the operating voltage. In other words, the I-MOS transistor will have a much lower turn-on power.

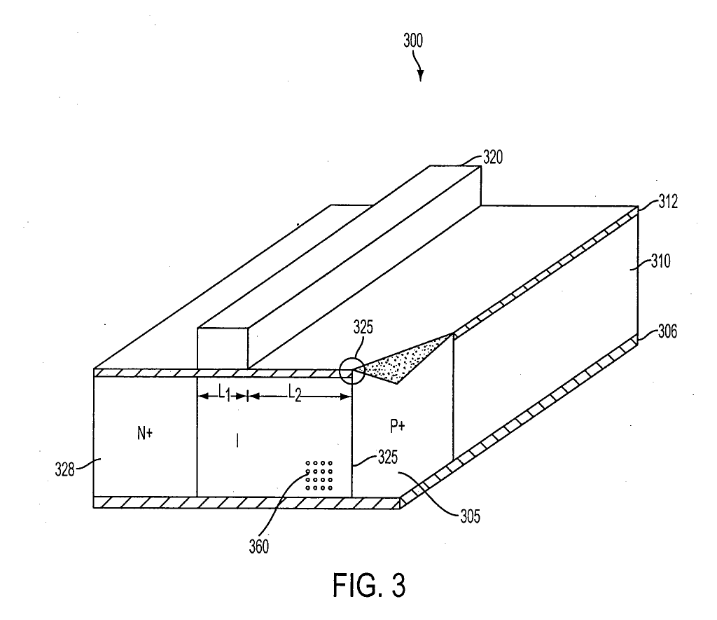

FIG. 3 shows a device according to another embodiment of the disclosure having mid-gap defects for directing avalanche breakdown. Device 300 of FIG. 3 can define an I-MOS. Device 300 includes gate electrode 320, drain electrode 328 and source electrode 305. Source electrode 305 provides sharp junction 325 with semiconductor body 310. Device 300 also includes gate oxide layer 312 and substrate 305. A plurality of mid-gap defect centers 360 is positioned at region L₂ of substrate 310. In one embodiment of the disclosure, mid-gap defect centers 360 comprise defect-induced micro-plasma and are used to control the exact location of avalanche breakdown in the I-MOSFET. By specifically locating the avalanche breakdown in the L₂ region (the un-gated I-region of semiconductor body 310, away from the gate), hot carrier injection into the gate oxide can be reduced. Furthermore, by locally instilling defects in the un-gated I-region, the semiconductor band-gap is effectively reduced. Because avalanche injection requires initiation by band-to-band transitions, the reduction substantially decreases the breakdown voltage and again is leveraged to function at larger geometries than I-MOS.

Mid-gap defect centers can comprise material having lower band-gap energy than the semiconductor body. In one embodiment of the disclosure, the mid-gap defect centers include Co, Zn, Cu, Au, Fe, Ni.

The embodiment of device 300 includes sharp junctions 325 as well as the mid-gap defects 360. However, each of the concepts (i.e., sharp junction or mid-gap defect) can be used separately to reach the desired results. That is, an I-MOS can be configured to have mid-gap defect centers alone or it can be configured to have the mid-gap defect centers in addition to an electrode having one or more sharp interfaces with the semiconductor body.

Using the sharp junction and mid gap defect centers together relaxes device geometries by an order of magnitude. Electrically, operation under Vds=IV is possible, with extremely abrupt sub-threshold slope of 10 mV/decade. Because avalanche multiplication is separated from the gate oxide, hot carrier injection into the gate oxide is suppressed.

The embodiments of the disclosure address some of the fundamental limits of semiconductor technology: sub-threshold slope below 60 mV/decade, voltage scaling below Vds=1 V and avoiding dimensional scaling below 25 nm geometries. As such, it is particularly suited to all advanced logic integrated circuits.

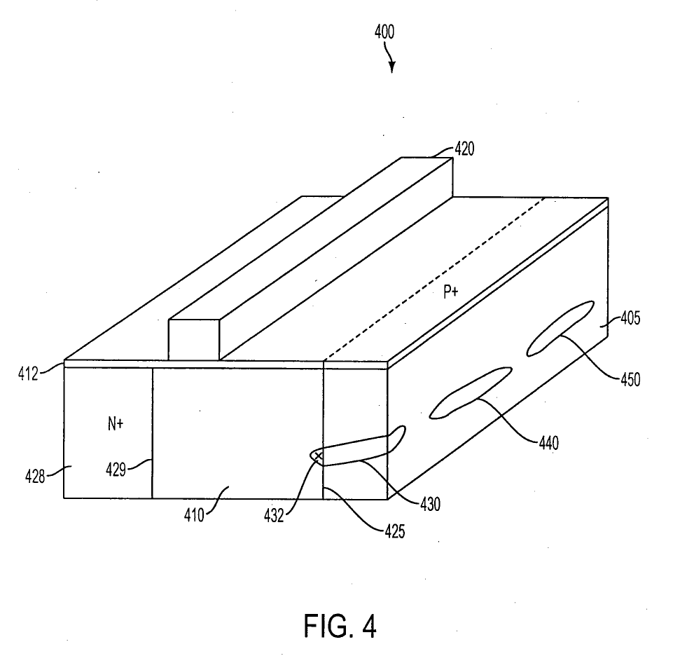

FIG. 4 is a schematic representation of a semiconductor device having a plurality of Nano-dots according to another embodiment of the disclosure. The device of FIG. 4 can be characterized as a Nano-dot Assisted Cool Impact ionization MOS (“NACIMOS”). Device 400 of FIG. 4 can comprises an I-MOS. As in FIGS. 2 and 3, Device 400 includes semiconductor body 410, drain electrode 428 (depicted as N+), source electrode 405 (depicted as P+) and gate electrode 420. Drain electrode 425 has interface 429 with semiconductor body 410. Source electrode 405 forms interface 425 with semiconductor body 410. Gate oxide layer 412 is interposed between gate electrode 420 and semiconductor body 410. Gate electrode 412 is positioned proximal to drain electrode 428 and distal from source electrode 405. In an embodiment of the disclosure, gate electrode 420 can be positioned equidistance from each of the drain electrode 428 and source electrode 405.

Nano-dots 430, 440 and 450 are positioned throughout source electrode 405 such that a Nano-dot Assisted Cool Impact Ionization MOS is formed. Each of nano-dots 430, 440 and 450 can comprise one or more material selected from the group including Ge, InAs, InAS₂, InSb, HgCdTe.

Other suitable material can also be selected such that the nano-dot has a lower breakdown voltage than the semiconductor body. Alternatively, any material or combination of material that lowers the band-gap energy of an electrode, as compared with silicon, can be used.

In one embodiment, the nano-dot is configured to have a sharp junction protruding into the semiconductor body 410. The sharp junctions provide a lower breakdown voltage as compare to a flat junction. In one embodiment, the sharp junction can include one or more avalanche carriers 432 Since the breakdown voltage is the voltage in which the device switches to an on state, the lower breakdown voltage allows the transistor to go on quicker and at a lower voltage. By providing a lower voltage, the disclosure provides a reduced voltage at which the transistor switched on.

In FIG. 4, avalanche carrier 432 extends into silicon body 410 as part of nano-dot 430. At the point of avalanche carrier generation, the carrier temperature is at its highest level. As carriers scatter in the semiconductor lattice, the energy is reduced. At the same time a certain amount of energy is necessary to excite carriers into the gate oxide of MOSFET. By especially locating the focused electric filed away from the gate oxide, hot carrier effects can be substantially removed. As a point of reference, the relaxation length in silicon is about 650 Angstrom. The relaxation length is a key parameter in the geometry of the basic device. Further, in the NACIMOS device, the actual point of impact ionization is in the avalanche carrier, resulting in lower initial energy and smaller distance between the avalanche center and gate oxide layer 412.

Thus, by specifically controlling the location of nano-dots 430, 440 and 450, the point of avalanche carrier generation can be designed away from gate oxide 412, thereby avoiding the massive threshold shifts and instabilities which are associated with hot carrier junction.

TABLE 1 shows a comparison of the NACIMOS to The International Technology Roadmap for Semiconductors (ITRS) goals. As can be seen, an NACIMOS device according to the principles disclosed herein exceeds the ITRS goals set for the year 2020.

TABLE 1
Performance data for NACIMOS & ITRS Goals

| | ITRS for 2020 | NACIMOS | Units |
|---|---|---|---|
| Subthreshold_Slope | 60 | 5 | mV/decade |
| V_{dd} | 0.5 | 0.4 | V |
| Ids leakage | 0.02* | 0.01 | μA/μm |
| Pstandby | 0.01* | 0.004 | μA/μm |

*means no known solutions.

The device shown in FIG. 4 lowers the voltage necessary to achieve avalanche breakdown for several reasons. First, because silicon (Eg=1.1 eV) is replaced in a portion of the I-silicon region with germanium (Eg=0.66 eV), a lower electric field is needed to achieve breakdown. The impact of such an enhancement is a factor of approximately 2-3.

Second, the finite radius of curvature of the germanium nano-dots lowers the breakdown by providing a sharp point which intensely focuses the electric field. This effect is expected to reduce the breakdown voltage by 5-6× from the case of a planar junction. Therefore, the total reduction in breakdown, and hence operating voltage, is expected drop by approximately one order of magnitude. Because IMOS devices have been operated at 8V, the operational voltage of the NACIMOS will reduce Vds to well under 1V, exceeding the expectations of low standby power devices in the ITRS beyond 2020. Alternately, the fundamental gains achieved in on-off current ratio can be parlayed into goal-breaking high performance logic or low operating power devices.

At the point of avalanche carrier generation, the carrier temperature is at its highest level. As carriers scatter in the semiconductor lattice, the energy is reduced. At the same time a certain amount of energy is necessary to excite carriers into the gate oxide of a MOSFET. By specifically locating the focused electric field away from the gate oxide, hot carrier effects can be substantially removed. As a point of reference, it has been determined that in silicon, the relaxation length is about 650 Angstroms. This can serve as a key parameter in the geometry of the basic device.

Furthermore, in the NACIMOS device, the actual point of impact ionization is inside the germanium resulting somewhat lower initial energy and perhaps smaller distance between the avalanche center and the gate oxide. Therefore, by specifically controlling the location of the germanium (or other suitable material) nano-dots, the point of avalanche carrier generation can be designed away from the gate oxide, avoiding the massive threshold shifts and instabilities associated with hot from the gate oxide, avoiding the massive threshold shifts and instabilities associated with hot carrier injection altogether.

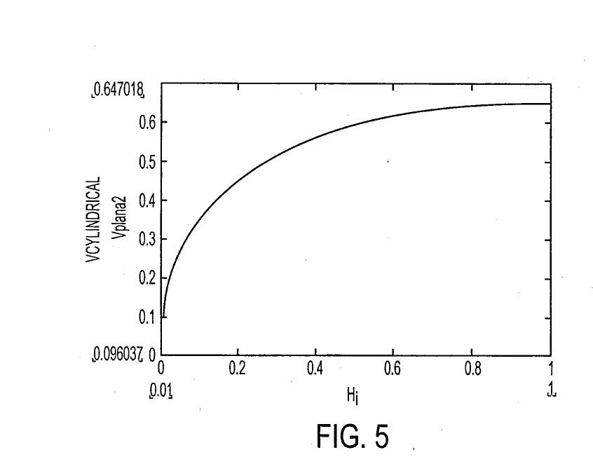

FIG. 5 shows simulated breakdown degradation factors as a function of junction sharpness. In FIG. 5, the X-axis shows the ratio between ration of the junction sharpness and the depletion width at the breakdown. The Y-axis shows the breakdown voltage for sharpened junction versus a planar junction. As can be seen from FIG. 5, by creating a non-planar junction, the critical electric field necessary for breakdown (E_{crit}) is substantially reduced. The reduction translates into a relaxation of the minimum geometry and a decrease in the operating voltage of the device.

While the principles of the disclosure have been illustrated in relation to the exemplary embodiments shown herein, the principles of the disclosure are not limited thereto and include any modification, variation or permutation thereof.

What is claimed is:

1. A low-power semiconductor switching device, comprising:
a substrate supporting thereon a semiconductor body;
a source electrode coupled to the semiconductor body at a source interface region;
a drain electrode coupled to the semiconductor body at a drain interface region;
a gate oxide film formed over a region of the semiconductor body, the gate oxide film interfacing between a gate electrode and the semiconductor body;
wherein at least one of the source interface region or the drain interface region defines a sharp junction into the semiconductor body.

2. The device of claim 1, wherein the sharp junction is a projection of one of the source electrode or the drain electrode into the semiconductor body.

3. The device of claim 1, wherein the sharp junction defines a plurality of protrusions of one of the source electrode or the drain electrode into the semiconductor body.

4. The device of claim 1, wherein the sharp junction is proximal to the gate electrode.

5. The device of claim 1, wherein the sharp junction is distal to the gate electrode.

6. The device of claim 1, wherein the sharp junction is an extension of the source electrode into the semiconductor body.

7. The device of claim 1, wherein the sharp junction is an extension of the drain electrode into the semiconductor body.

8. The device of claim 1, wherein the sharp junction defines an abrupt junction between the source electrode and the semiconductor body.

9. The device of claim 1, wherein the sharp junction increases an avalanche potential at the junction between the source electrode and the semiconductor body.

10. The device of claim 1, wherein each of the source interface region and the drain interface region defines a sharp junction with the semiconductor body.

11. The device of claim 1, wherein the switching device activates to an on state at a range of about 0.4 to 1.0 V.

12. A method for providing a low-power transistor, the method comprising:
providing a substrate having thereon a semiconductor body;
forming a source electrode on the substrate, the source electrode having a source interface with the semiconductor body;
forming a drain electrode on the substrate, the drain electrode having a drain interface with the semiconductor body;
forming a gate electrode over a portion of the semiconductor body;
defining at least one of the source interface or the drain interface to provide a sharp junction with the semiconductor body.

13. The method of claim 12, wherein the sharp junction forms a non-planar edge protruding into the semiconductor body.

14. The method of claim 12, wherein the sharp junction further comprises a plurality of protrusions into the semiconductor body.

15. The method of claim 12, wherein the sharp junction is a projection of one of the source electrode or the drain electrode into the semiconductor body.

16. The method of claim 12, further comprising forming the sharp junction proximal to the gate electrode.

17. The method of claim 12, further comprising forming the sharp junction distal to the gate electrode.

18. The method of claim 12, further comprising forming the sharp junction as an extension of one of the source electrode or the drain electrode into a region of the semiconductor body not covered by the gate electrode.

19. The method of claim 12, further comprising forming the sharp junction as an extension of one the source electrode and the drain electrode into the semiconductor body.

20. The method of claim 12, further comprising increasing an avalanche potential at the junction between the source electrode and the semiconductor body.

21. A low-power transistor, comprising:
a source electrode;
a drain electrode;
a gate electrode;
a semiconductor body region in electronic communication with each of the source electrode, the drain electrode and the gate electrode, the semiconductor body region having a plurality of mid-gap defect centers;
the mid-gap defect centers form micro-plasma within a region of the semiconductor body to control a location of electronic avalanche breakdown in a region distal from the gate electrode.

22. The low-power transistor of claim 21, wherein the mid-gap defect centers diminish a hot carrier injection.

23. The low-power transistor of claim 21, wherein the mid-gap defect centers are formed at a region of the semiconductor body not covered by the gate electrode.

24. The low-power transistor of claim 21, wherein the mid-gap defect centers are formed throughout the semiconductor body at a region not covered by the gate electrode.

25. The low-power transistor of claim 21, wherein the mid-gap defect centers are localized at a region proximal to the drain electrode or the gate electrode.

26. The low-power transistor of claim 21, wherein the mid-gap defect centers are localized at a first region proximal to the drain electrode and at a second region proximal to the source electrode.

27. The low-power transistor of claim 21, wherein the mid-gap defect centers comprise one of a low band-gap material or a mid band-gap material.

28. The low-power transistor of claim 21, wherein the mid-gap defect centers are selected from the group consisting of Co, Zn, Cu, Au, Fe, Ni.

29. The low-power transistor of claim 21, wherein the mid-gap defect centers are doped into the semiconductor body.

30. The low-power transistor of claim 21, wherein at least one of the source region or the drain region forms an interface with the semiconductor body, the interface having a sharp junction.

31. The low-power transistor of claim 30, wherein the sharp junction defines a projection of an electrode into the semiconductor body.

32. A method for providing low power in a MOSFET, the method comprising:
providing a semiconductor body;
forming a source electrode in electronic communication with the semiconductor body, the source electrode having a source interface with the semiconductor body;
forming a drain electrode in electronic communication with the semiconductor body, the drain electrode having a drain interface with the semiconductor body;
forming a gate electrode over a portion of the semiconductor body;
forming a plurality of mid-gap defect centers in the semiconductor body;
wherein the mid-gap defect centers are formed as micro-plasma within a region of the semiconductor body for controlling a location of electronic avalanche breakdown.

33. The method of claim 32, wherein the mid-gap defect centers are doped into the semiconductor body.

34. The method of claim 32, further comprising diminishing a hot carrier injection at the mid-gap defect centers.

35. The method of claim 32, further comprising forming the mid-gap defect centers at a region not covered by the gate electrode.

36. The method of claim 32, further comprising forming the mid-gap defect centers at a region proximal to the drain electrode or the source electrode.

37. The method of claim 32, further comprising forming the mid-gap defect centers at a first region proximal to the drain electrode and at a second region proximal to the source electrode.

38. The method of claim 32, further comprising forming the mid-gap defect centers from a material having one of a low band-gap energy or mid band-gap energy.

39. The method of claim 32, further comprising forming at least one of the source interface or the drain interface with a sharp junction with the semiconductor body.

40. The method of claim 39, wherein the plurality of mid-gap defect centers are formed proximal to the sharp junction.

41. The method of claim 39, wherein the plurality of mid-gap defect centers are formed distal to the sharp junction.

42. The method of claim 32, wherein the plurality of mid-gap are formed from defect-induced micro-plasma.

43. A low power transistor device, comprising:
a substrate supporting a semiconductor body;
a source electrode coupled to the semiconductor body at a source interface region;
a drain electrode coupled to the semiconductor body at a drain interface region;
a gate oxide film formed over a region of the semiconductor body, the gate oxide film interfacing between a gate electrode and the semiconductor body;
wherein at least one of the source electrode or the drain electrode includes a first nano-dot, and
wherein the first nano-dot is formed from a first material having a band-gap energy lower than a band-gap energy of the semiconductor body.

44. The device of claim 43, further comprising a second nano-dot.

45. The device of claim 43, wherein the first nano-dot further comprises an avalanche carrier electron.

46. The device of claim 43, wherein the first nano-dot defines a geometric shape having a sharp junction.

47. The device of claim 46, wherein the sharp junction extends into the semiconductor body.

48. The device of claim 43, wherein the first nano-dot is disposed within one of the source electrode or the drain electrode.

49. The device of claim 43, wherein the first nano-dot comprises a plurality of first nano-dots disposed within the source electrode and the drain electrode.

50. The device of claim 43, wherein the first nano-dot extends from one of the source electrode or the gate electrode to a region within the semiconductor body.

51. The device of claim 43, wherein the first nano-dot extends from the source electrode to a region within the semiconductor body distal from the gate electrode.

52. The device of claim 43, wherein the first nano-dot is disposed within the source electrode extending to a region of the semiconductor body not covered by the gate electrode.

53. The device of claim 43, wherein the first nano-dot is disposed within the source electrode and a second nano-dot is disposed within the drain electrode and wherein each of the first nano-dot and the second nano-dot extend into the a region of the semiconductor body not covered by the gate electrode.

54. The device of claim 43, wherein each of the first nano dot and the second nano-dot include a sharp junction which extends into the semiconductor body.

55. The device of claim 43, wherein the first nano-dot comprises Ge, InAs, InSb, or HgCdTe.

56. The device of claim 43, wherein the first nano-dot is formed from a high-energy band-gap material.

57. The device of claim 43, further comprising a second nano-dot formed from a second material having a lower band-gap energy than the semiconductor body.

58. The device of claim 43, wherein the source interface region comprises a sharp junction with the semiconductor body.

59. The device of claim 43, further comprising a second nano-dot formed from a second material, wherein at least one of the first material or the second material provides an electronic band-gap energy higher than a band-gap energy of the semiconductor body.

60. A method for providing rapid switching in a field-effect transistor (“FET”), comprising:
providing a substrate having a semiconductor body thereon;
forming a source electrode on the substrate, the source electrode having a source interface with the semiconductor body;
forming a drain electrode on the substrate, the drain electrode having a drain interface with the semiconductor body;
forming a gate electrode over a portion of the semiconductor body; and
forming a first nano-dot within at least one of the source electrode or the drain electrode;
wherein the first nano-dot is formed from a first material having a lower band-gap energy than the band-gap energy of the semiconductor body.

61. The method of claim 60, wherein at least one of the source interface or the drain interface includes a sharp junction with the semiconductor body.

62. The method of claim 60, further comprising forming a second nano-dot formed from a second material.

63. The method of claim 62, wherein the second material is the same as the first material.

64. The method of claim 60, wherein the first nano-dot further comprises an avalanche carrier electron.

65. The method of claim 60, further comprising forming the first nano-dot to have a sharp junction.

66. The method of claim 65, wherein the sharp junction extends into a region within the semiconductor body.

67. The method of claim 60, wherein the first nano-dot comprises a plurality of first nano-dots disposed within the source electrode or the drain electrode.

68. The method of claim 60, further comprising extending the first nano-dot from one of the source electrode or the gate electrode to a region within the semiconductor body.

69. The method of claim 60, wherein the first nano-dot is disposed within the source electrode extending to a region of the semiconductor body not covered by the gate electrode.

70. The method of claim 60, wherein the first nano-dot is disposed within the source electrode and a second nano-dot is disposed within the drain electrode and wherein each of the first nano-dot and the second nano-dot extend into the a region of the semiconductor body not covered by the gate electrode.

71. The device of claim 60, further comprising forming the first nano-dot from one of a high-energy band-gap material or a mid-energy band-gap material.

72. The device of claim 60, further comprising extending at least a portion of the nano-dot to a region of the semiconductor body not covered by the gate electrode.
